(19) United States
(12) Patent Application Publication
(10) Pub. No.: US 2008/0151506 A1
(43) Pub. Date: Jun. 26, 2008

(54) Printed circuit board having vertical heat dissipating element

(75) Inventors: Tung-Hsing Tsou, Hsinchu County (TW); Cheng-Kang Wen, Hsinchu County (TW); Chang-Lung Li, Hsinchu County (TW)

Correspondence Address: Joe McKinney Muncy, PO Box 1364, Fairfax, VA, 22038-1364, US

(73) Assignee: CHENG HOME ELECTRONICS CO., LTD.

(21) Appl. No.: 11/641,710

(22) Filed: Dec. 20, 2006

(51) Int. Cl. H05K 7/20

(52) U.S. Cl. 361/719

(57) ABSTRACT

A printed circuit board having vertical heat dissipating element is characterized in that a substrate of the printed circuit board is made of metal and has a first surface and a second surface, and plural metallic heat dissipating elements are mounted on the first surface of the substrate and the second surface of the substrate is spread by an insulation layer, on which a circuit layer is disposed.

### FIELD OF THE INVENTION

The present invention is related to a printed circuit board (PCB), and more particularly to a printed circuit board having vertical heat dissipating element.

### BACKGROUND OF THE INVENTION

The conventional substrate is phenolic aldehyde plate (so called electric wood plate) or FRP (Fiberglass Reinforced Plastics) made of unsaturated polyester resin and glass fiber, wherein FRP can bear water, medicine, heat, etch and has great surface tension and high degree of intensity, so that it is gradually accepted. However, when some electronic elements which are easy to produce heat, such as high effect CPU or LED chip, are mounted on phenolic aldehyde plate or FRP, the produced heat might not be dissipated quick enough so as to cause damage, even danger.

Therefore, other materials, such as, metal (commonly, aluminum or copper or the alloy thereof), are used as the substrate of the printed circuit board. For example, R.O.C Patent No. I260793 discloses a LED package structure employing the aluminum-copper substrate includes: a substrate made of at least one selected from the combinations constituted by aluminum and copper; an electrode layer located on the substrate; a high reflectivity alloy layer located on the electrode layer and having macromolecular adhesive applied on a portion thereof to form joint points, wherein the macromolecular adhesive includes epoxy resin having carbon, hydrogen, oxygen radical, and one or two of acid anhydride and amine; a chip fixed on the joint point; and a cover located on the electrode layer for covering the chip.

However, the efficiency of current electronic components (such as, high effect CPU or LED chip) is gradually increased, and also the power and heat producing rate, especially the power of one single LED chip has already dramatically jumped from decades of milliwatt to several watts, so that the metallic substrate is not enough to dissipate the heat, which obviously might cause damage due to the overheated working temperature and also danger. Consequently, how to overcome the drawbacks described above has become the main purpose of electronic industry.

### SUMMARY OF THE INVENTION

The object of the present invention is to utilize plural metal heat dissipating elements vertically located on a first surface of the substrate, thereby quickly exhausting the heat from the circuit layer on the second surface so as to achieve a fast heat dissipation.

For achieving the object described above, the present invention provides a printed circuit board having vertical heat dissipating elements, characterized in that: a substrate of the printed circuit board is made of metal and has a first surface and a second surface, and plural metallic heat dispersing elements are mounted on the first surface of the substrate and the second surface of the substrate is spread by an insulation layer, on which a circuit layer is disposed.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a schematic view showing the decomposition structure of a embodiment according to the present invention; and

FIG. 2 is a schematic view showing the decomposition structure of another embodiment according to the present invention.

### DESCRIPTION OF THE PREFERRED EMBODIMENT

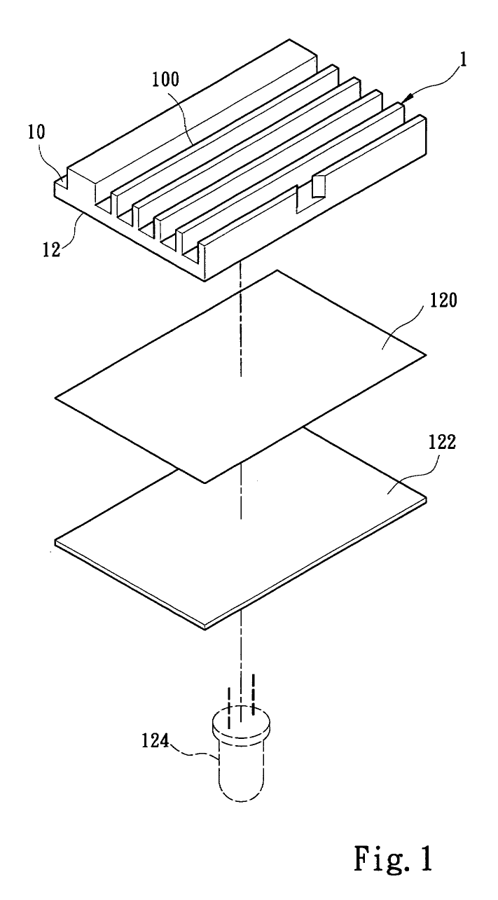

Please refer to FIG. 1, which is a schematic view showing the decomposition structure of a preferred embodiment in the present invention.

The present invention provides a PCB having vertical heat dissipating element, characterized in that: a substrate 1 of the PCB is made of metal, preferably aluminum, copper, aluminum alloy, aluminum-copper alloy, and the substrate 1 has a first surface 10 and a second surface 12. In this embodiment, the first surface 10 and the second surface 12 are opposite planes, wherein plural metal heat dissipating elements 100 are mounted on the first surface of the substrate 1, in which the metal heat dissipating element 100 is a heat dissipating fin, and the second surface 12 of the substrate 1 is spread by an insulation layer 120, on which a circuit layer 122 is disposed, and the circuit layer 122 is electrically connected to a LED (light emitting diode) chip 124, which is easy to generate a high amount of heat. Preferably, the substrate 1 and the metal heat dissipating element 100 are integrally formed, thereby quickly dissipating the heat from the first surface having the circuit layer 122 to the metal heat dissipating element 100 of the second surface 12.

Therefore, through the metal heat dissipating element 100 on the first surface 10 of the substrate 1, the contact area of substrate 1 with the air can be increased, so that the heat produced by the circuit layer 122 on the second surface 12 of the substrate 1 can be quickly exhausted, thereby preventing the electronic components (such as LED chip 124) connected to the circuit layer 122 from being damaged by overheated working temperature.

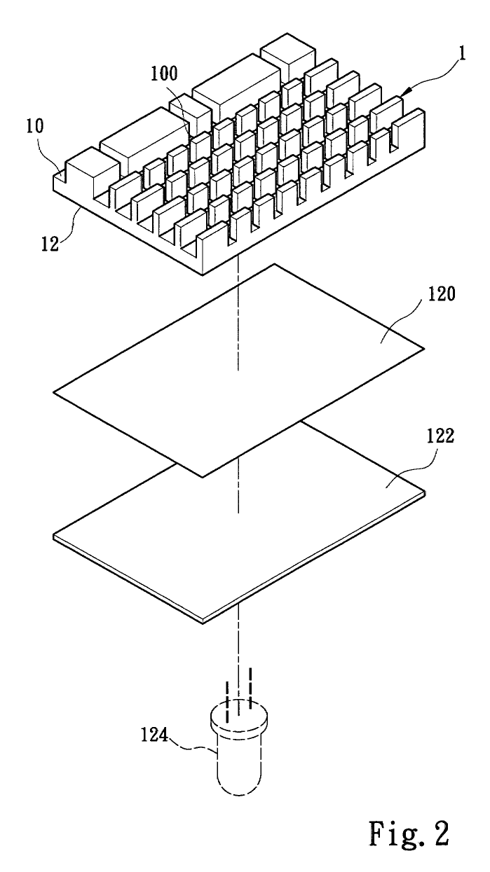

Please refer to FIG. 2, which is a schematic view showing the decomposition structure of another embodiment according to the present invention. The difference between this embodiment and the previous embodiment is that the metal heat dissipating element 100 is formed to be heat dissipating pillar, and thus, under the same volume, the heat dissipating pillar can have a larger contact area with air than the above heat dissipating fin so as to provide a better heat dissipating effect.

In the aforesaid, because the present invention utilizes the metal heat dissipating element 100 to contact with the air, the heat produced by the circuit layer 122 can be quickly exhausted, thereby preventing the electronic components (such as LED chip 124) connected to the circuit layer 122 from being damaged by overheated working temperature and also avoiding the danger.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A printed circuit board having vertical heat dissipating element, characterized in that:
a substrate of the printed circuit board is made of metal and has a first surface and a second surface, and plural metallic heat dissipating elements are mounted on the first surface of the substrate and the second surface of the substrate is spread by an insulation layer, on which a circuit layer is disposed.

2. The printed circuit board as claimed in claim 1, wherein the substrate and the metal heat dissipating element are integrally formed.

3. The printed circuit board as claimed in claim 1, wherein the substrate is made of one selected from aluminum, copper and combination thereof.

4. The printed circuit board as claimed in claim 1, wherein the circuit layer is electrically connected to a LED chip.

5. The printed circuit board as claimed in claim 1, wherein the metal heat dissipating element is a heat dissipating fin.

6. The printed circuit board as claimed in claim 1, wherein the metal heat dissipating element is a heat dissipating pillar.

7. The printed circuit board as claimed in claim 1, wherein the first surface and the second surface are two opposite planes.
